(19) United States
(12) Patent Application Publication
(10) Pub. No.: US 2010/0132984 A1
(43) Pub. Date: Jun. 3, 2010

(54) MULTILAYER PRINTED CIRCUIT BOARD

(75) Inventors: Yuya Narazako, Daito City (JP); Kazunari Sakaki, Osaka-shi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: SANYO ELECTRIC CO., LTD., Osaka (JP)

(21) Appl. No.: 12/629,162

(22) Filed: Dec. 2, 2009

(30) Foreign Application Priority Data
Dec. 2, 2008 (JP) 2008-307309

(51) Int. Cl. H05K 1/03; H05K 1/16

(52) U.S. Cl. 174/255; 174/260

(57) ABSTRACT

In order to reduce noise propagating from a digital signal circuit to an analog signal circuit, a multilayer printed circuit board includes a first digital signal circuit formed in a first region of a front surface, a first analog signal circuit formed in a second region of the front surface, a second digital signal circuit formed at a back surface corresponding to the first region, a second analog signal circuit formed at the back surface corresponding to the second region; an analog ground circuit formed between the front surface and the back surface to ground the first analog signal circuit and the second analog signal circuit, and a first digital ground circuit arranged between the first digital signal circuit and the analog ground circuit and a second digital ground circuit arranged between the second digital signal circuit and the analog ground circuit to ground the first digital signal circuit and the second digital signal circuit.

This application is based on Japanese Patent Application No. 2008-307309 filed with Japan Patent Office on Dec. 2, 2008, the entire content of which is hereby incorporated by reference.

### BACKGROUND OF THE INVENTION

1. Field of the Invention

The present invention relates to a multilayer printed circuit board, and more particularly to a multilayer printed circuit board formed of a digital signal circuit and an analog signal circuit.

2. Description of the Related Art

Analog signal circuits for high-frequency signals are known to easily cause EMI (Electro Magnetic Interference). Therefore, Japanese Patent Laid-Open No. 2003-298245 discloses a technique of fabricating a multilayer circuit board having a ground pattern formed between a front surface and a back surface for analog signal circuits formed on the front surface and the back surface.

On the other hand, a technique of forming an analog signal circuit and a digital signal circuit in the same printed circuit board is known. According to this technique, in a multilayer printed circuit board, in order to prevent noise from intruding into an analog signal circuit from a digital signal circuit, a region in which a digital signal circuit is formed and a region in which an analog signal circuit is formed are separately arranged such that the digital signal circuit and the analog signal circuit do not overlap each other in the interlayer.

However, when a digital signal circuit and an analog signal circuit are formed so as not to overlap each other in the interlayer in a multilayer printed circuit board, the area for the analog signal circuit is inevitably limited. On the other hand, in the analog signal circuit for receiving high-frequency radio signals, the area for a ground circuit needs to be made large in order to improve reception sensitivity. Thus, if the area for the analog signal circuit is limited, the area for the ground circuit cannot be increased.

### SUMMARY OF THE INVENTION

The present invention is made to solve the aforementioned problem. An object of the present invention is to provide a multilayer printed circuit board in which noise propagating from a digital signal circuit to an analog signal circuit can be prevented.

In order to solve the aforementioned problem, in accordance with an aspect of the present invention, a multilayer printed circuit board includes: a first digital signal circuit formed in a first region of a front surface to process a digital signal; a first analog signal circuit formed in a second region of the front surface to process an analog signal; a second digital signal circuit formed in a third region of a back surface corresponding to the first region and electrically connected to the first digital signal circuit; a second analog signal circuit formed in a fourth region of the back surface corresponding to the second region and electrically connected to the first analog signal circuit; an analog ground circuit formed between the front surface, and the back surface to ground the first analog signal circuit and the second analog signal circuit; and first and second digital ground circuits to ground the first digital signal circuit and the second digital signal circuit. The first digital ground circuit is arranged between the first digital signal circuit and the analog ground circuit. The second digital ground circuit is arranged between the second digital signal circuit and the analog ground circuit.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 shows a cross section of a multilayer printed circuit board in an embodiment of the present invention.

### DESCRIPTION OF THE PREFERRED EMBODIMENTS

In the following, an embodiment of the present invention will be described with reference to the FIGURE. In the following description, the same components are denoted with the same reference numerals. They have the same names and functions. Therefore, a detailed description thereof will not be repeated.

In the present embodiment, a multilayer printed circuit board mounted on a digital camera is described. This multilayer printed circuit board includes, in combination, an analog signal circuit for processing GPS signals received by a GPS (Global Positioning System) antenna and a digital signal circuit for executing an image pickup function of a digital camera. In the analog signal circuit that receives and processes a GPS signal of a weak radio wave, a large area is preferably allocated to a wiring pattern for grounding the analog signal circuit in order to improve reception sensitivity.

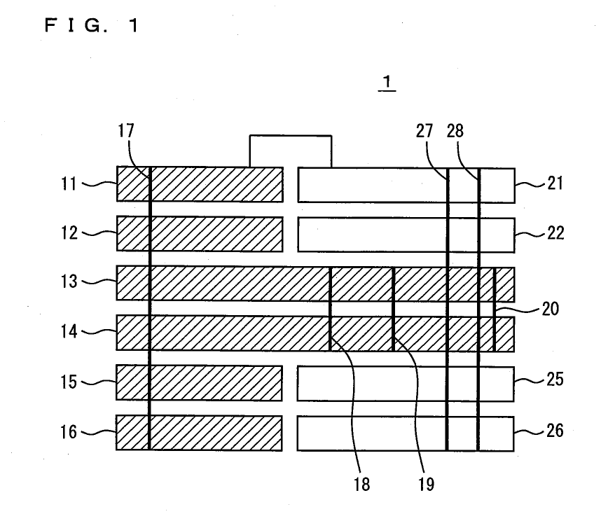

FIG. 1 shows a cross section of a multilayer printed circuit board in the present embodiment. Referring to FIG. 1, a multilayer printed circuit board 1 is formed of six layers. Each of the first and sixth layers corresponds to an outer surface of the multilayer printed circuit board. Here, the first layer is referred to as a front surface of multilayer printed circuit board 1, and the sixth layer is referred to as a back surface of multilayer printed circuit board 1.

Formed in the first layer are a first analog signal circuit 11 having a GPS antenna mounted thereon and a first digital signal circuit 21 having an IC or the like mounted thereon for processing digital signals. Formed in the second layer are a first analog ground circuit 12 having a ground pattern for analog signals and a first digital ground circuit 22 having a ground pattern for digital signals. In the third layer and the fourth layer, second and third analog ground circuits 13, 14 each having a ground pattern for analog signals are respectively formed across the entire multilayer printed circuit board 1. Formed in the fifth layer are a fourth analog ground circuit 15 having a ground pattern for analog signals and a second digital ground circuit 25 having a ground pattern for digital signals. Formed in the sixth layer, which is the outer surface (back surface) of the multilayer printed circuit board, are a second analog signal circuit 16 having an analog signal circuit having an IC or the like mounted thereon for processing a signal received by the GPS antenna and a second digital signal circuit 26 having an IC or the like mounted thereon for processing digital signals.

First analog signal circuit 11, first analog ground circuit 12, fourth analog ground circuit 15, and second analog signal circuit 16 have equal areas and are arranged to overlap each other. Similarly, first digital signal circuit 21, first digital ground circuit 22, second digital ground circuit 25, and second digital signal circuit 26 have equal areas and are arranged to overlap each other.

First analog signal circuit 11, first to fourth analog ground circuits 12, 13, 14, 15, and second analog signal circuit 16 are connected with each other via a through-hole 17. Furthermore, second and third analog ground circuits 13, 14 are electrically connected with each other via through-holes 18, 19, 20 at respective different locations.

Furthermore, first digital signal circuit 21, second and third digital ground circuits 22, 25, and second digital signal circuit 26 are electrically connected with each other via through-holes 27, 28. It is noted that through-holes 27, 28 pass through but are insulated from second and third analog ground circuits 13, 14.

First digital signal circuit 21 and first analog signal circuit 11 are arranged in different regions at the front surface of multilayer printed circuit board 1. Here, the region in which first digital signal circuit 21 is formed is called a first region, and the region in which first analog signal circuit 11 is formed is called a second region. On the other hand, second digital signal circuit 26 and second analog signal circuit 16 are arranged in different regions at the back surface of multilayer printed circuit board 1. Here, the region in which second digital signal circuit 26 is formed is called a third region, and the region in which second analog signal circuit 16 is formed is called a fourth region.

The fourth region in which second analog signal circuit 16 is formed has an area equal to that of the second region in which first analog signal circuit 11 is formed, and is arranged at the back surface of multilayer printed circuit board 1 corresponding to the second region. Therefore, between first analog signal circuit 11 and second analog signal circuit 16, only first to fourth analog ground circuits 12, 13, 14, 15 are arranged, and a circuit through which a digital signal flows is not arranged.

The third region in which second digital signal circuit 26 is formed has an area equal to that of the first region in which the first digital signal circuit is formed, and is arranged at the back surface of multilayer printed circuit board 1 corresponding to the first region. Between first digital signal circuit 21 and second digital signal circuit 26, third analog ground circuit 13 is arranged in the second layer, a part of second analog ground circuit 13 is arranged in the third layer, a part of third analog ground circuit 14 is arranged in the fourth layer, and second digital ground circuit 25 is arranged in the fifth layer.

First digital ground circuit 22 has an area equal to that of first digital signal circuit 21 and is arranged to overlap first digital signal circuit 21 in the interlayer. Similarly, second digital ground circuit 25 has an area equal to that of second digital signal circuit 26 and is arranged to overlap second digital signal circuit 26 in the interlayer. Here, a description is given of a case where first digital ground circuit 22 and first digital signal circuit 21 have equal areas and second digital ground circuit 25 and second digital signal circuit 26 have equal areas. However, first digital ground circuit 22 may have an area equal to or larger than the area of first digital signal circuit 21 and be arranged between first digital signal circuit 21 and second analog ground circuit 13. Similarly, second digital ground circuit 25 may have an area equal to or larger than second digital signal circuit 26 and be arranged between second digital signal circuit 26 and third analog ground circuit 14.

Between first digital signal circuit 21 and second digital signal circuit 26, a part of second analog ground circuit 13 and a part of third analog ground circuit 14 are arranged. However, first digital ground circuit 22 is arranged in the second layer between first digital signal circuit 21 in the first layer and third analog ground circuit 13 in the third layer, and second digital ground circuit 25 is arranged in the fifth layer between second digital signal circuit 26 in the sixth layer and a part of fourth analog ground circuit 14 in the fourth layer. Therefore, noise propagating from first digital signal circuit 21 and second digital signal circuit 26 to second analog ground circuit 13 and third analog ground circuit 14 can be reduced.

In multilayer printed circuit board 1 in the present embodiment, first analog signal circuit 11 and second analog signal circuit 16 are electrically isolated from first digital signal circuit 21 and second digital signal circuit 26 by a shield formed by second and third analog ground circuits 13, 14 and first and second digital ground circuits 22, 25. Accordingly, noise resulting from first digital signal circuit 21 and second digital signal circuit 26 can be suppressed in first analog signal circuit 11 and second analog signal circuit 16.

Furthermore, since second and third analog ground circuits 13, 14 can be formed across the entire multilayer printed circuit board 1, the areas of the ground circuits can be made as large as possible, thereby stabilizing a reference potential at a time of reception of a GPS signal and improving the reception sensitivity. As a result, the gain of the antenna can be improved.

As described above, in multilayer printed circuit board 1 in the present embodiment, first digital ground circuit 22 is arranged between first digital signal circuit 21 formed at the front surface and second analog ground circuit 13, and second digital ground circuit 25 is arranged between second digital signal circuit 26 formed at the back surface and third analog ground circuit 14. Therefore, first digital ground circuit 22 and second analog ground circuit 13 as well as second digital ground circuit 25 and third analog ground circuit 14 form a shield so that noise propagating from first digital signal circuit 21 and second digital signal circuit 26 to first analog signal circuit 11 and second analog signal circuit 16 can be reduced.

In addition, second and third analog ground circuits 13, 14 are formed across the entire multilayer printed circuit board. Therefore, the areas of second and third analog ground circuits 13, 14 can be made large, so that the reference potential of first and second analog signal circuits 11, 16 can be stabilized. As a result, the reception sensitivity of a GPS signal can be improved.

Moreover, second and third analog ground circuits 13, 14 are formed in multiple layers, namely, the third layer and the fourth layer. Therefore, the area of the ground circuit can be made even larger than when the ground circuit is formed in a single layer. It is noted that the ground circuit can be formed in any multiple number of layers, i.e. two or more layers.

In addition, second and third analog ground circuits 13, 14 are electrically connected with each other at a plurality of different locations via through-holes 17, 18, 19, 20. Therefore, the reference potential of first and second analog signal circuits 11, 16 can be stabilized more.

Multilayer printed circuit board 1 in the present embodiment can be applied to portable equipment such as digital cameras for which circuit grounding is difficult.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A multilayer printed circuit board comprising:
a first digital signal circuit formed in a first region of a front surface to process a digital signal;
a first analog signal circuit formed in a second region of said front surface to process an analog signal;
a second digital signal circuit formed in a third region of a back surface corresponding to said first region and electrically connected to said first digital signal circuit;
a second analog signal circuit formed in a fourth region of said back surface corresponding to said second region and electrically connected to said first analog signal circuit;
an analog ground circuit formed between said front surface and said back surface to ground said first analog signal circuit and said second analog signal circuit; and
first and second digital ground circuits to ground said first digital signal circuit and said second digital signal circuit, wherein
said first digital ground circuit is arranged between said first digital signal circuit and said analog ground circuit, and
said second digital ground circuit is arranged between said second digital signal circuit and said analog ground circuit.

2. The multilayer printed circuit board according to claim 1, wherein said analog ground circuit is formed across the entire multilayer printed circuit board.

3. The multilayer printed circuit board according to claim 2, wherein said analog ground circuit is formed in a plurality of layers.

4. The multilayer printed circuit board according to claim 3, wherein a plurality of analog ground circuits formed in said plurality of layers are electrically connected with each other at a plurality of different locations.

5. The multilayer printed circuit board according to claim 1, wherein said analog ground circuit is formed in a plurality of layers.
